(19) United States
(12) Patent Application Publication
(10) Pub. No.: US 2006/0267620 A1
(43) Pub. Date: Nov. 30, 2006

(54) Interconnecting apparatus and a contact element therefor

(76) Inventor: Kim Huat Ang, Singapore (SG)

Correspondence Address: SUGHRUE MION, PLLC, 2100 PENNSYLVANIA AVENUE, N.W., SUITE 800, WASHINGTON, DC, 20037, US

(21) Appl. No.: 10/546,027

(22) PCT Filed: Feb. 19, 2003
(86) PCT No.: PCT/SG03/00034

§ 371 Date: Jun. 27, 2006

(51) Int. Cl. G01R 31/26

(52) U.S. Cl. 324/765

(57) ABSTRACT

An interconnecting apparatus (10) is disclosed for use in testing electronic devices. The apparatus (10) includes a housing portion (12, 14) provided with a plurality of apertures extending between oppositely facing first and second surfaces of the housing portion (12, 14) and a plurality of contact elements (16), each contact element (16) being disposed in an aperture. Each contact element (16) is a helical spring formed of electrically conductive material, a first end portion of each spring being located adjacent the first surface of the housing portion (12, 14) and a second opposite end portion of each spring being located adjacent the second surface of the housing portion (12, 14). Each spring is configured so that the diameter of the spring decreases in a direction away from the first end portion. The arrangement is such that during use the first end portion receives and makes electrical connection with a device contact of an electronic device under test and the second end portion makes electrical connection with a test contact of a test board.

### FIELD OF THE INVENTION

The present invention relates to an interconnecting apparatus for use in testing electronic devices and to a contact element for use with the interconnecting apparatus.

### BACKGROUND OF THE INVENTION

It is known to provide an interconnecting apparatus which is useable to electrically connect an electronic device to be tested with a test board configured to carry out predetermined tests on the electronic device.

Such known interconnecting apparatus essentially take the form of a housing provided with a plurality of apertures, each aperture extending between two oppositely facing surfaces of the housing and each aperture receiving a contact element having one or more pins resiliently biased in a direction outwardly of the housing. Generally, the contact elements include a spring disposed in a barrel shaped enclosure to resiliently bias the pins.

During use, an electronic device and a test board are disposed relative to the housing such that the pins make electrical connection with respective contacts on the electronic device and the test board and the desired electrical connections are made between the electronic device and the test board.

However, as electronic circuits become smaller, so the diameter of the contact elements must also become smaller. Also, in some applications, for example high frequency testing of integrated circuits, it is desirable to minimise distortion by reducing the contact length between the electronic device under test and the test board as much as possible.

As a consequence, conventional contact elements which generally include four components are difficult and costly to manufacture.

Furthermore, reducing the diameter of the contact pins of the contact elements increases the risk of causing damage to electrical contacts on the electronic device under test and on the test board.

### SUMMARY OF THE INVENTION

In accordance with a first aspect of the present invention, there is provided an interconnecting apparatus for use in testing electronic devices, said apparatus including:
a housing portion provided with a plurality of apertures extending between oppositely facing first and second surfaces of the housing portion; and
a plurality of contact elements, each said contact element being disposed in an aperture;
wherein each contact element is a helical spring formed of electrically conductive material, a first end portion of said spring being located adjacent the first surface of the housing portion and a second opposite end portion of said spring being located adjacent the second surface of the housing portion, said spring being configured so that the diameter of said spring decreases in a direction away from the first end portion;
the arrangement being such that during use the first end portion receives and makes electrical connection with a device contact of an electronic device under test and the second end portion makes electrical connection with a test contact of a test board.

In a preferred embodiment, the housing portion includes a first housing portion and a second housing portion fixable to the first housing portion.

Preferably, each aperture includes an aperture portion of enlarged diameter for receiving in use the first end portion of a spring and thereby retaining the spring in the housing.

Preferably, said spring includes a first spring portion of substantially cup-like configuration and a second elongate spring portion of substantially constant diameter.

In accordance with a second aspect of the present invention, there is provided a contact element for use in an interconnecting apparatus for testing electronic devices, wherein said contact element is a helical spring formed of electrically conductive material, a first end portion of said spring being configured such that the diameter of said spring decreases in a direction away from the first end portion, the arrangement being such that during use a device contact of an electronic device under test is receivable in the first end portion so as to make electrical connection with the first end portion.

### BRIEF DESCRIPTION OF THE DRAWINGS

The present invention will now be described, by way of example only, with reference to the accompanying drawings, in which:

FIG. 1 is a diagrammatic representation in cross-section of a portion of an interconnecting apparatus in accordance with an embodiment of the present invention;

FIG. 2 is a diagrammatic exploded representation in cross-section of the portion of the interconnecting apparatus shown in FIG. 1;

FIG. 3 is a diagrammatic plan view of a contact element of the interconnecting apparatus shown in FIGS. 1 and 2;

FIG. 4 is a diagrammatic perspective view of the contact element shown in FIG. 3; and

FIG. 5 is a diagrammatic representation in cross-section of the portion of the interconnecting apparatus shown in FIGS. 1 and 2 in electrical connection with an electronic device and a test board during use.

### DESCRIPTION OF A PREFERRED EMBODIMENT OF THE PRESENT INVENTION

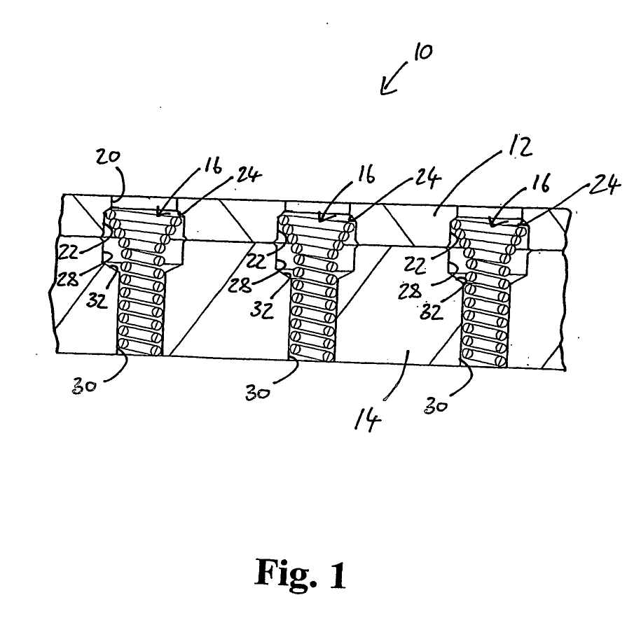

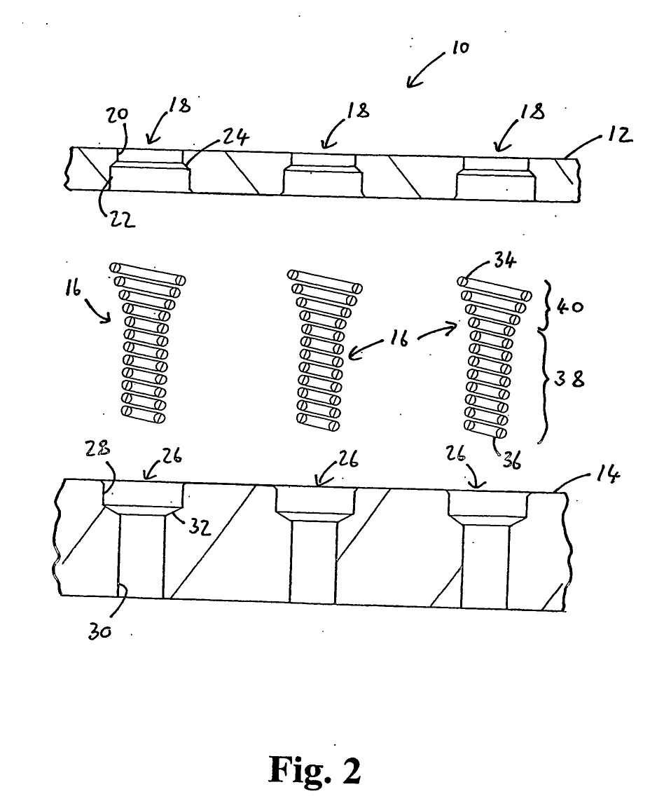

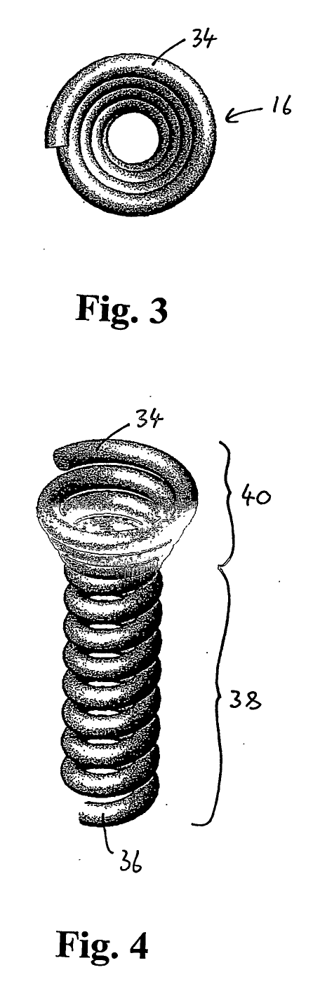

Referring to the drawings, in FIGS. 1 and 2 there is shown a portion of an interconnecting apparatus 10 for use in testing electronic devices. The apparatus 10 includes a housing, in this example having an upper housing portion 12 and a lower housing portion 14 connected together in any suitable way, for example using screws. Disposed in the housing 12, 14 are a plurality of contact elements in the form of helical springs 16.

It will be understood that although FIGS. 1 and 2 show a portion of an interconnecting apparatus 10 and only 3 springs are illustrated, in practice any number of springs may be provided. The springs may be disposed in the housing in any one or two dimensional configuration. In the present example, the springs 16 are disposed in the housing in a square-shaped configuration.

As can be seen more particularly in FIG. 2, the upper housing portion 12 includes a plurality of first apertures 18. Each of the apertures 18 includes a first aperture portion 20 and a second aperture portion 22 of enlarged diameter relative to the first aperture portion 20. Between the first and second aperture portions 20, 22 is a shoulder portion 24.

Likewise, the lower housing portion 14 includes a plurality of second apertures 26. Each second aperture 26 includes a first aperture portion 28 and a second aperture portion 30 of reduced diameter relative to the first aperture portion 28. Between the first and second aperture portions 28, 30 is a shoulder portion 32.

Each helical spring 16 has a first end portion 34 and a second opposite end portion 36. In this example, each helical spring 16 includes a first spring portion 38 of generally constant diameter and a second spring portion 40, the diameter of which reduces in a direction inwardly of the spring 16 from the first end portion 34. In this example, the second spring portion 40 is of generally cup-like configuration.

The springs 16 are formed so as to be highly electrically conductive. In this example, the springs are formed of gold plated resilient metal.

In order to construct the interconnecting apparatus 10, each of the helical springs 16 is first inserted into a second aperture 26 such that the first spring portion 38 extends through the second aperture portion 30 of the second aperture 26. The upper housing portion 12 is then disposed on the lower housing portion 14 such that each second spring portion 40 extends into a second aperture portion 22 of a first aperture 18 and rests against a shoulder portion 24. The upper and lower housing portions 12, 14 are then fixed to each other in any suitable way, for example using screws.

As can be seen more particularly in FIG. 1, since the second spring portion 40 of each spring 16 is of enlarged diameter relative to the first spring portion 38 and locates in an aperture portion of enlarged diameter, once the upper and lower housing portions 12, 14 have been fixed together the springs 16 are held in position relative to the housing.

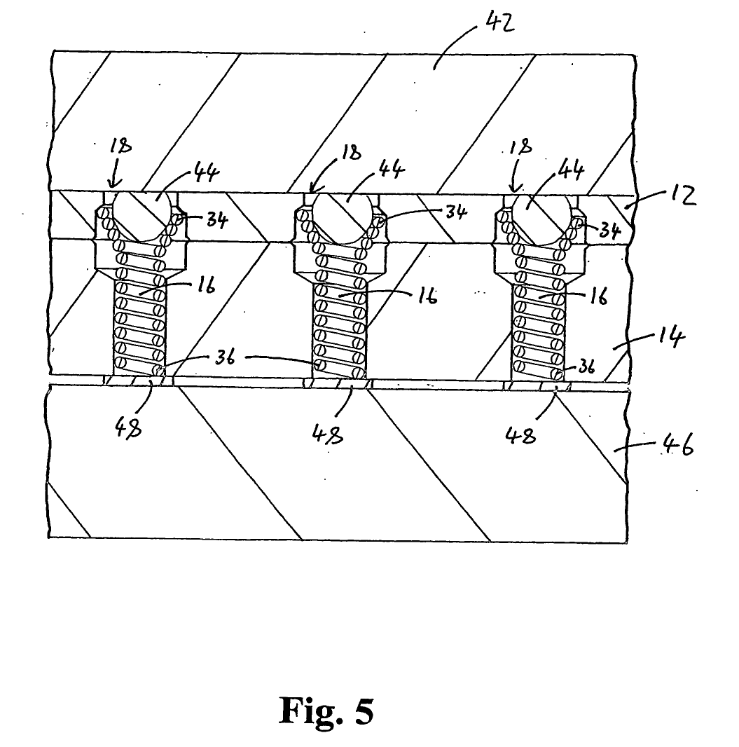

The interconnecting apparatus 10 is shown in use in FIG. 5.

As shown in FIG. 5, in order to carry out testing of an electronic device 42, for example an integrated circuit, the electrical device 42 is engaged with the interconnecting apparatus 10 by passing device contacts 44 of the electronic device 42 through the first apertures 18 so that the device contacts 44 press down on and make electrical connection with the second spring portions 40. A device test board 46 having test board contacts 48 is brought into contact with the second end portions 36 of the springs 16 which extend through the second aperture portions 30 of the lower housing portion 14. The test board contacts 48 may be maintained in electrical contact with the second end portions 36 in any suitable way, for example by fixing the interconnecting apparatus 10 to the test board 46 by locating pins and screws.

It will be understood that since the second spring portion 40 of each spring 16 is of generally cup-like configuration, the likelihood of causing damage to the device contacts 44 is much reduced relative to conventional contact elements. This is because during use the device contacts 44 are received in the second spring portions and the device contacts are not contacted by sharp pins as is the case with conventional contact elements.

It will also be understood that disposing the device contacts 44 in the first apertures 18 causes the springs 16 to compress and uppermost turns of the springs 16 to contact each other and thereby shorten the electrical path between the first and second end portions 34, 36 of the springs 16.

It will also be understood that since the second end portions 36 of the springs 16 is helical shaped, the likelihood of causing damage to the test board contacts 48 is much reduced relative to existing contact elements. This is because during use the test board contacts 48 are not contacted by sharp pins as is the case with conventional contact elements.

It will also be understood that since the present contact element includes only a single component, the degree of manufacturing difficulty and cost is much reduced relative to conventional contact elements.

Modifications and variations as would be apparent to a skilled addressee are deemed to be within the scope of the present invention.

1. An interconnecting apparatus for use in testing electronic devices, said apparatus including:
a housing portion provided with a plurality of apertures extending between oppositely facing first and second surfaces of the housing portion; and
a plurality of contact elements, each said contact element being disposed in an aperture;
wherein each contact element is a helical spring formed of electrically conductive material, a first end portion of said spring being located adjacent the first surface of the housing portion and a second opposite end portion of said spring being located adjacent the second surface of the housing portion, said spring being configured so that the diameter of said spring decreases in a direction away from the first end portion;
the arrangement being such that during use the first end portion receives and makes electrical connection with a device contact of an electronic device under test and the second end portion makes electrical connection with a test contact of a test board.

2. An interconnecting apparatus as claimed in claim 1, wherein the housing portion includes a first housing portion and a second housing portion fixable to the first housing portion.

3. An interconnecting apparatus as claimed in claim 1, wherein each aperture includes an aperture portion of enlarged diameter for receiving in use the first end portion of a spring and thereby retaining the spring in the housing.

4. An interconnecting apparatus as claimed in any one of claims 1 to 3, wherein said spring includes a first spring portion of substantially cup-like configuration and a second elongate spring portion of substantially constant diameter.

5. A contact element for use in an interconnecting apparatus for testing electronic devices, wherein said contact element is a helical spring formed of electrically conductive material, a first end portion of said spring being configured such that the diameter of said spring decreases in a direction away from the first end portion, the arrangement being such that during use a device contact of an electronic device under test is receivable in the first end portion so as to make electrical connection with the first end portion.

6. A contact element as claimed in claim 5, wherein said spring includes a first spring portion of substantially cup-like configuration and a second spring portion of substantially constant diameter.
